(19) United States
(12) Patent Application Publication
(10) Pub. No.: US 2015/0340602 A1
(43) Pub. Date: Nov. 26, 2015

(54) METHOD TO FORM SMALL MRAM CELL BY COLLIMATED OXYGEN ION IMPLANTATION

(71) Applicant: Yimin Guo, San Jose, CA (US)

(72) Inventor: Yimin Guo, San Jose, CA (US)

(73) Assignee: T3MEMORY, INC., Saratoga, CA (US)

(21) Appl. No.: 14/285,637

(22) Filed: May 23, 2014

(51) Int. Cl. H01L 43/12; H01L 43/02; H01L 43/10; H01L 43/08

(52) U.S. Cl. CPC H01L 43/12; H01L 43/08; H01L 43/02; H01L 43/10

(57) ABSTRACT

A method to form a small magnetic random access memory (MRAM) cell using collimated oxygen ion implantation is provided. With a proper control of the bias voltage and collimation angle, oxygen ions are impinged into the magnetic memory layers with a desired energy and bombardment angle, yielding a sharp oxygen boundary around the memory cell. After a high temperature anneal, a dielectric matrix with good metal-oxide bonding is formed within the oxygen implanted memory region and thus forming a small MRAM cell in the mask protected area.

### RELATED APPLICATIONS

This application claims the priority benefit of U.S. Provisional Application No. 61/827,610 filed on May 26, 2013, which is incorporated herein by reference.

### BACKGROUND OF THE INVENTION

1. Field of the Invention

This invention relates generally to spin-electronic devices, more particularly to a method to make a magnetic random access memory using collimated oxygen ion implantation.

2. Description of the Related Art

Magnetoresistive elements having magnetic tunnel junctions (also called MTJs) have been used as magnetic sensing elements for years. In recent years, magnetic random access memories (hereinafter referred to as MRAMs) using the magnetoresistive effect of MTJ have been drawing increasing attention as the next-generation solid-state nonvolatile memories that can cope with high-speed reading and writing, large capacities, and low-power-consumption operations. A ferromagnetic tunnel junction has a three-layer stack structure formed by stacking a recording layer having a changeable magnetization direction, an insulating spacing layer, and a fixed layer that is located on the opposite side from the recording layer and maintains a predetermined magnetization direction.

2. Description of the Related Art

Magnetoresistive elements having magnetic tunnel junctions (also called MTJs) have been used as magnetic sensing elements for years. In recent years, magnetic random access memories (hereinafter referred to as MRAMs) using the magnetoresistive effect of MTJ have been drawing increasing attention as the next-generation solid-state nonvolatile memories that can cope with high-speed reading and writing, large capacities, and low-power-consumption operations. A ferromagnetic tunnel junction has a three-layer stack structure formed by stacking a recording layer having a changeable magnetization direction, an insulating spacing layer, and a fixed layer that is located on the opposite side from the recording layer and maintains a predetermined magnetization direction.

As a write method to be used in such magnetoresistive elements, there has been suggested a write method (spin torque transfer switching technique) using spin momentum transfers. According to this method, the magnetization direction of a recording layer is reversed by applying a spin-polarized current to the magnetoresistive element. Furthermore, as the volume of the magnetic layer forming the recording layer is smaller, the injected spin-polarized current to write or switch can be also smaller. Accordingly, this method is expected to be a write method that can achieve both device miniaturization and lower currents.

Further, as in a so-called perpendicular MTJ element, both two magnetization films have easy axis of magnetization in a direction perpendicular to the film plane due to their strong magnetic crystalline anisotropy, shape anisotropies are not used, and accordingly, the device shape can be made smaller than that of an in-plane magnetization type. Also, variance in the easy axis of magnetization can be made smaller. Accordingly, by using a material having a large magnetic crystalline anisotropy, both miniaturization and lower currents can be expected to be achieved while a thermal disturbance resistance is maintained.

There has been a known technique for achieving a high MR ratio in a perpendicular magnetoresistive element by forming a crystallization acceleration film that accelerates crystallization and is in contact with an interfacial magnetic film having an amorphous structure. As the crystallization acceleration film is formed, crystallization is accelerated from the tunnel barrier layer side, and the interfaces with the tunnel barrier layer and the interfacial magnetic film are matched to each other. By using this technique, a high MR ratio can be achieved. However, where a MTJ is formed as a device of a perpendicular magnetization type, the materials of the recording layer typically used in an in-plane MTJ for both high MR and low damping constant as required by low write current application normally don't have enough magnetic crystalline anisotropy to achieve thermally stable perpendicular magnetization against its demagnetization field. In order to obtain perpendicular magnetization with enough thermal stability, the recording layer has to be ferromagnetic coupled to additional perpendicular magnetization layer, such as TbCoFe, or CoPt, or multilayer such as (Co/Pt)n, to obtain enough perpendicular anisotropy. Doing so, reduction in write current becomes difficult due to the fact that damping constant increases from the additional perpendicular magnetization layer and its associated seed layer for crystal matching and material diffusion during the heat treatment in the device manufacturing process.

In a spin-injection MRAM using a perpendicular magnetization film, a write current is proportional to the perpendicular anisotropy, the damping constant and inversely proportional to a spin polarization, and increases in proportional to a square of an area size. Therefore, reduction of the damping constant, increase of the spin polarization and reduction of an area size are mandatory technologies to reduce the write current.

Besides a write current, the stability of the magnetic orientation in a MRAM cell as another critical parameter has to be kept high enough for a good data retention, and is typically characterized by the so-called thermal factor which is proportional to the perpendicular anisotropy as well as the volume of the recording layer cell size. Although a high perpendicular anisotropy is preferred in term of a high thermal disturbance resistance, an increased write current is expected as a cost.

To record information or change resistance state, typically a recording current is provided by its CMOS transistor to flow in the stacked direction of the magnetoresistive element, which is hereinafter referred to as a “vertical spin-transfer method.” Generally, constant-voltage recording is performed when recording is performed in a memory device accompanied by a resistance change. In a STT-MRAM, the majority of the applied voltage is acting on a thin oxide layer (tunnel barrier layer) which is about 10 angstroms thick, and, if an excessive voltage is applied, the tunnel barrier breaks down. More, even when the tunnel barrier does not immediately break down, if recording operations are repeated, the element may still become nonfunctional such that the resistance value changes (decreases) and information readout errors increase, making the element un-recordable. Furthermore, recording is not performed unless a sufficient voltage or sufficient spin current is applied. Accordingly, problems with insufficient recording arise before possible tunnel barrier breaks down.

In the mean time, since the switching current requirements reduce with decreasing MTJ element dimensions, STT-MRAM has the potential to scale nicely at even the most advanced technology nodes. However, patterning of small MTJ element leads to increasing variability in MTJ resistance and sustaining relatively high switching current or recording voltage variation in a STT-MRAM.

Reading STT MRAM involves applying a voltage to the MTJ stack to discover whether the MTJ element states at high resistance or low. However, a relatively high voltage needs to be applied to the MTJ to correctly determine whether its resistance is high or low, and the current passed at this voltage leaves little difference between the read-voltage and the write-voltage. Any fluctuation in the electrical characteristics of individual MTJs at advanced technology nodes could cause what was intended as a read-current, to have the effect of a write-current, thus reversing the direction of magnetization of the recording layer in MTJ. Majorities of cell-to-cell variations come from the MTJ cell patterning process.

The MTJ patterning process becomes one of the most challenging aspects of manufacturing. Conventional techniques utilized to pattern small dimensions in a chip, such as ion milling etching (IBE) or reactive ion etching (RIE), having been less than satisfactory when applied to magnetic tunnel junction stacks used for MRAM. In most cases when these techniques are used, it is very difficult or almost impossible to cleanly remove etched materials without partial damages to magnetic tunnel junction properties and electric current shunting. In a RIE etching of magnetic material, physical sputtering is still the major component which unavoidable results in the formation of re-deposited residues that can short circuit the junctions of the MTJ or create shunting channel of the MTJ, yielding high resistance variations and serious reliability issues.

Another problem of conventional patterning techniques is the degradation of the recording layer and reference layer in the MTJ, due to corrosion caused by chemical residue remaining after etching. Exposure to reactive gases during refilling deposition of dielectrics such as silicon dioxide or silicon nitride after the MTJ etching can also cause corrosion. After refilling of dielectric material, a chemical mechanic polishing process is required to smooth out the top surface for bit line fabrication, which introduces a big manufacturing challenging as well as high cost and further corrosion.

Thus, it is desirable to provide a greatly improved method or innovative method that enables well-controllable and low cost fabrication in MTJ patterning while eliminating damage, degradation and corrosion.

The conventional fabrication method to form STT-MRAM is by etching and dielectric refilling. Due to a weaker ion bombardment during etch at the lower portion of the MTJ pillar; the sensor profile is typically sloped with narrow top and wide bottom. As the result, the formed sensor size cannot be made small enough to reduce the write current to switch the memory layer. Also, due to the non-volatile nature of the etched magnetic materials, often the etched sensor edge got damaged with electrical shorting across the MgO barrier.

In our previous invention application, we disclosed a method to form magnetic random access memory (MRAM) by oxygen plasma ion implantation. In the plasma process chamber (FIG. 1), the accelerated oxygen ions are impinged into the negatively biased substrate at a desired depth below the device surface and form a region of metal oxide surrounding the MRAM cell.

Due to the nature of chamber geometry, the oxygen ions impinging onto the device surface are NOT perfectly perpendicular to the device surface, thus creating a wide boundary (120 & 140 in FIG. 2) between the memory cell (140, 120) and the metal oxide matrix (130) formed by the oxygen ion implantation. To make a small MRAM with a well defined device region, the width of such boundary should be reduced.

### BRIEF SUMMARY OF THE PRESENT INVENTION

The present invention is about a method to make magnetic random access memory (MRAM), in particular, perpendicular spin transfer torque MRAM or p-STT-MRAM. Electrically isolated memory cell is formed by ion implantation instead of etching and dielectric refill. A method to form a small magnetic random access memory (MRAM) cell using collimated oxygen ion implantation is provided. With a proper control of the bias voltage and collimation angle, oxygen ions are impinged into the magnetic memory layers with a desired energy and bombardment angle, yielding a sharp oxygen boundary around the memory cell. An ultra-thin single-layer or multiple-layer of oxygen-getter, selected from Mg, Zr, Y, Th, Ti, Al, Ba is inserted below and above the active magnetic memory layer in addition to putting a thicker such material above and below the memory layer to effectively capture the impinged oxygen ions. Oxygen is further confined within the core device layer by adding oxygen stopping layer below the bottom oxygen-getter. After a high temperature anneal, a dielectric matrix with good metal-oxide bonding is formed within the oxygen implanted memory region and thus forming a small MRAM cell in the mask protected area.

### BRIEF DESCRIPTION OF THE DRAWINGS

FIG. 1 Schematic view of oxygen plasma based ion implantation system.

FIG. 2 MRAM cross section formed by oxygen plasma ion implantation.

FIG. 3 Typical MRAM film stack with oxygen gettering layer and ion mask layer.

FIG. 4 The formed MRAM cell with sharp magnetic/oxide boundary.

FIG. 5 A series of collimator to confine oxygen ion impinging angles to a well defined direction with small divergence.

FIG. 6 A dielectric layer refilled at the etched portion of the device.

FIG. 7 A CMP used to flatten the wafer surface and remove the top portion of the oxidized ion-mask layer.

FIG. 8 A top metallic film stack deposited and subsequently patterned to form top electrode.

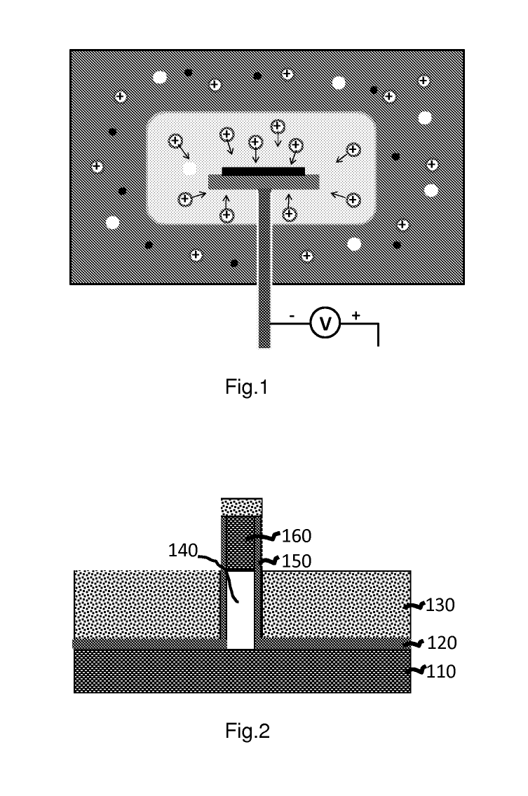

### DETAILED DESCRIPTION OF THE INVENTION

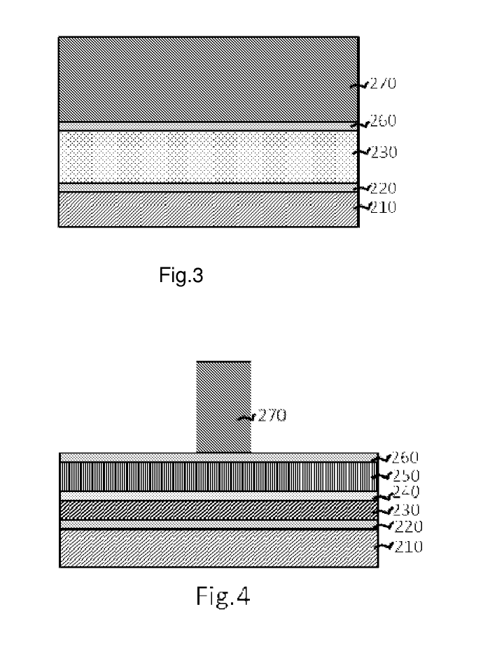

The first step is to deposit a device film stack on a Si substrate which may already contain CMOS control circuits. In general, the process described here can be used to make any type of integrated devices, such as diodes, FETs, and various RAMs including MRAM. The film (FIG. 3) stack contains several key layers, a bottom ion-stopping layer(210), an oxygen gettering layer(220), a device layer(230) which could contains a series of sub-layers, an ion-capping layer which also act as ion mask etching stopping layer (260), and an ion-mask layer (270).

The ion-stopping layer (210) typically contains a heavy metal with large atomic number, selected from Hf, Ta, W, Re, Os, Ir, Pt, Au, with a thickness between 200 A-1000 A. Au or Pt is superior to other materials because of their resistance to oxygen oxidation. The oxygen gettering layer (220 & 260) typically contains a material selected among Mg, Zr, Y, Th, Ti, Al, Ba below the active memory film stack (230-250, see FIG. 4) region to effectively capture oxygen ions during oxygen ion implantation. For magnetic random access memory application, Mg is preferred due to its close lattice constant match with CoFeB. The thickness of the oxygen gettering layer (220) is typically about 50 A-100 A.

The memory core stack (230), such as for perpendicular spin transfer torque memory random access memory (pSTT-MRAM), typically contains three key sub-layers (see FIG. 4): CoFeB memory layer (230) with a thickness between 10 A-30 A, MgO dielectric tunneling layer (240) with a thickness between 8-15 A, and a magnetic reference layer (250) made from a hard magnetic materials, allow of CoPt, CoPd, CoTb, FePt, FePd, FeTb or multilayer of [CoFe/Ni]n, [Co/Ni]n, [Co/Pt]n, [Co/Pd]n, [Fe/Pt]n with a total thickness between 30 A-80 A. The ion-capping layer (260) has two functions: first to prevent oxygen ions backing-off during oxygen ion implantation and, second to act as a reactive ion etch (RIE) stopping layer for the formation of the top ion-mask layer (270). The ion-capping layer can be selected from Ru, Cu, Al, Cr with a thickness between 100 A-300 A. The top ion-mask layer (270), in general, uses the same material as the bottom ion-stopping layer (210), such as Ta, W, Hf, Re, Os, Ir, Pt, Au. For MRAM, Ta is preferred because of its ease in CF4 RIE process during the mask formation.

After the film deposition, a photolithography patterning is performed, which can be either a single patterning or dual patterning. The patterned wafer is then RIE etched to remove the exposed mask material. For Ta ion mask, typical etchant is CF4 or CF3H or other C,F,H containing gases. The etching is stopped on top of the ion-capping layer (260). Then oxygen plasma is used to remove the remaining photoresist and etchant re-dep. The formed ion-mask (270) is shown in FIG. 4.

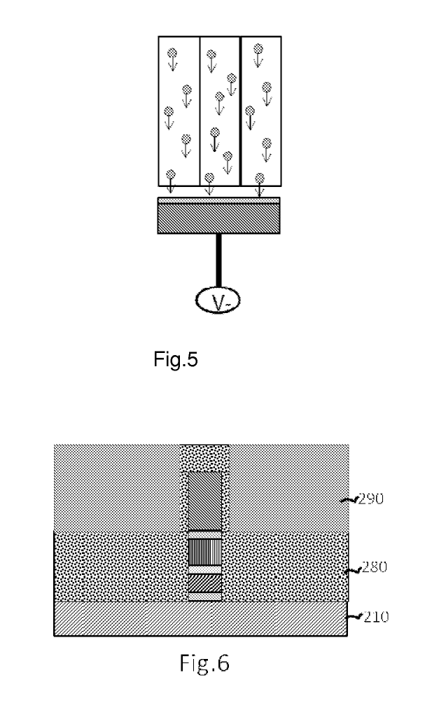

Then immediately followed by plasma (300) generated oxygen ion implantation to add oxygen into the memory core layers (230-250). To effectively accelerate oxygen ions into the buried film stack, the whole wafer is negatively biased. Before reaching the device surface, the oxygen ions pass through a series of collimator (as shown in FIG. 5) to confine their impinging angles to a well defined direction with small divergence.

To avoid over-heating, the plasma power may be pulsed. Due to the presence of ion stopping layer (210), oxygen ions are mainly captured by the oxygen gettering layer (220) and redistributed into the memory core layers (230-250) thus forming a new metal oxide dielectric layer (280) with an uniform oxygen re-distribution across it after a high temperature anneal. In the mean time, the top portion of the ion-mask layer (270) is also oxidized as shown in FIG. 6.

For low cost, a conventional oxygen plasma chamber with a negatively biased substrate can also be used to do film oxidation as long as the oxygen ions O+ has high enough kinetic energy to impinged into the film stack. Also, a conventional ion beam etching (IBE) chamber can be adapted to do oxygen ion implantation by replacing the conventional metal grid with a noble metal such as Pt or Ir to avoid grid oxidation.

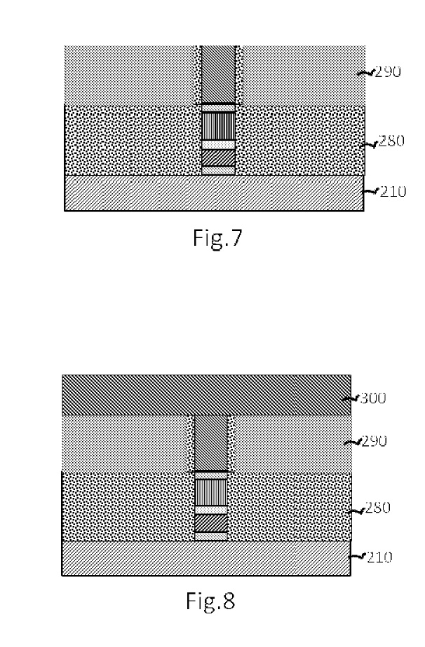

Then a dielectric SiO2, SiNx or Al2O3 layer (290) is refilled at the etched portion of the device (see FIG. 6), and a chemical mechanic polishing (CMP) is used to flatten the wafer surface and also remove the top portion of the oxidized ion-mask layer (FIG. 7). Then a top metallic film stack (300) is deposited and subsequently patterned to form top electrode (FIG. 8), which can be a single metallic layer of Ru, Cu, Al or alloy of them or sandwiched between two Ta layers, with a thickness of 500 to 1000 A.

The wafer is finally annealed at high temperature between 250 C to 500 C for a time between 30 sec to 30 minutes to activate the oxygen-metallic bonding for form metal oxide electrically insulating dielectric matrix and also to repair the damage from oxygen ion implantation.

1. An integrated circuit electronic device is created by a collimated oxygen plasma oxidization.

2. The element of claim 1, wherein said integrated circuit electronic device is a magnetic random access memory (MRAM).

3. The element of claim 1, wherein said integrated circuit electronic device is a spin transfer torque magnetic random access memory (STT-MRAM), further a perpendicular spin torque transfer magnetic random access memory (pSTT-MRAM).

4. The element of claim 1, wherein said integrated circuit device contains an ion implantation stopping layer, an oxygen gettering layer, an active device layer, an ion-capping layer, and ion-mask layer.

5. The element of claim 4, wherein said oxygen plasma ion stopping layer is selected from the group of Hf, Ta, W, Re, Os, Ir, Pt, Au, and has a thickness between 20 nm and 50 nm, and Pt, Au is preferred.

6. The element of claim 4, wherein said oxygen gettering layer is selected from the group Mg, Zr, Y, Th, Ti, Al, Ba, and has a thickness between 2 nm and 10 nm, and Mg is preferred.

7. The element of claim 3, wherein said pSTT-MRAM contains a CoFeB memory layer having a thickness between 1 nm and 3 nm, an MgO dielectric tunneling layer having a thickness between 0.8 nm and 1.5 nm and a magnetic reference layer of CoPt, or CoPd, CoTb, FePt, FePd, FeTb or [CoFe/Ni]n, [Co/Pt]n, [Co/Pd]n, [Fe/Pt]n, [FePd]]n multilayer having a total thickness between 3 nm and 8 nm.

8. The element of claim 3, wherein said ion-capping layer is selected from the group of Ru, Cu, Al, Cr, and has a thickness between 10 nm and 30 nm, and Ru is preferred.

9. The element of claim 1, wherein the film stack of said integrated circuit device is patterned through a photolithography.

10. The element of claim 9, wherein an exposed ion mask region of said film stack in said patterned integrated circuit device is etched.

11. The element of claim 9, wherein said patterning consists of a Ta ion-mask and an etchant gas selected from CF4, CF3H, and other C,F,H containing chemical gases, the etching is stopped on top of an ion-capping layer.

12. The element of claim 11, wherein the etched ion-mask, the remaining photoresist and redep during said patterning is removed by oxygen burning.

13. The element of claim 9, wherein said patterning of said integrated circuit device further comprising an oxygen ion bombardment with certain ions dose and impinging energy to drive the oxygen ions into the active device region.

14. The element of claim 9, wherein said oxygen plasma oxidization comprising a plasma ionization to generate oxygen ions.

15. The element of claim 9, wherein during said oxygen plasma oxidization the wafer substrate of said device is negatively biased.

16. The element of claim 9, wherein during said oxygen plasma oxidization further comprising a pulsed plasma power to avoid substrate overheating.

17. The element of claim 9, wherein said oxygen oxidation is conducted in a conventional oxygen plasma chamber with negatively biased substrate.

18. The element of claim 9, wherein said oxygen oxidation is conducted in a conventional ion beam etching chamber with a metal grid made by a noble metal, such as Pt.

19. The element of claim 18, wherein said oxygen ions are collimated by collimators to create a well-defined impinging angle with small angle deviation.

20. The element of claim 19, wherein the impinged oxygen ions claimed above are stopped by bottom ion-stopping layer.

21. The element of claim 20, wherein the impinged oxygen ions claimed above are captured by oxygen gettering layer below the device region.

22. The element of claim 21, wherein the oxygen ion-implanted device wafer is etched to remove the exposed ion-capping layer to avoid electrical shorting.

23. The element of claim 22, wherein the oxygen ion-capping layer is Ru and the etchant gas is CH3OH, or CO & NH4.

24. The element of claim 23, wherein the etched device wafer is refilled with SiO2, SiNx, or AlOx dielectrics, and is subsequently chemical mechanical polished to flatten the surface and remove the top portion of the oxidized ion-mask.

25. The element of claim 24, wherein the CMP flattened device wafer is deposited with a metallic electrode layer made of Ru, Cu, Al or alloy of them or sandwiched between two Ta layers, Ta/Ru/Ta or Ta/Cu&Al alloy/Ta, with a thickness of 500 to 1000 A.

26. The element of claim 25, wherein the top electrode layer is patterned and etched to form electrode line.

27. The device wafer claimed above is high-temperature annealed between 250 C to 500 C for 30 seconds to 30 minutes to activate the metal-oxide bonding and to repair the device damage during oxygen ion implantation.
